(19) United States
(12) Patent Application Publication
(10) Pub. No.: US 2008/0219038 A1
(43) Pub. Date: Sep. 11, 2008

(54) FERROELECTRIC MEMORY DEVICE

(75) Inventor: Susumu SHUTO, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/042,839

(22) Filed: Mar. 5, 2008

(30) Foreign Application Priority Data
Mar. 6, 2007 (JP) 2007-056404

(51) Int. Cl. G11C 11/22

(52) U.S. Cl. 365/145

(57) ABSTRACT

Disclosed is a ferroelectric memory device. Multiple memory cells are connected between bit lines and a plate line, and constitute a memory cell array. Each of the memory cells is composed of a first ferroelectric capacitor and a memory cell transistor. The gates of the memory cell transistors are connected to multiple word lines, respectively. The bit lines are connected to multiple sense amplifiers for amplifying information. One end of the second ferroelectric capacitor is electrically connected to a corresponding one of the bit lines, and the other end of the second ferroelectric capacitor is electrically connected to a power supply.

### CROSS REFERENCE TO RELATED APPLICATION

This application is based upon and claims the benefit of priority from the prior Japanese Patent Application No. 2007-56404, filed on Mar. 6, 2007, the entire contents of which are incorporated herein by reference.

### FIELD OF THE INVENTION

The present invention relates to a ferroelectric memory device including ferroelectric memory cells.

### DESCRIPTION OF THE BACKGROUND

FeRAM (Ferroelectric Random Access Memory), MRAM (Magnetic Random Access Memory), PRAM (Phase Change Random Access Memory) and ReRAM (Resistive Random Access Memory) have been developed as next-generation semiconductor memory devices.

A FeRAM is disclosed in Japanese Patent Application Publication No. 2000-90674, for example. This patent application describes a FeRAM including a plurality of memory cells having a ferroelectric capacitor and a cell transistor respectively. FeRAM can be rewritten faster than a flash memory. FeRAM may achieve a greater number of rewriting operations than the flash memory.

The FeRAM described in the aforementioned patent application is provided with a memory cell block including memory cell arrays as a main storage unit. In addition to the memory cell block, a relatively small scale memory cell array is provided for storing management information or operation mode information. In such a FeRAM chip, a unit such as a CPU, a processor or the like may be embedded in addition to a FeRAM memory cell array. In the unit, a FeRAM may be provided to be used as a memory for storing a program or information.

In a large scale memory cell array, bit lines are long so that the parasitic capacitances of the bit lines are large. On the other hand, in a small scale memory cell array, bit lines are short so that the parasitic capacitances of the bit lines are small. Thus, in the small scale memory cell array, bit line capacitances are small so that bit line signal voltage differences are small at the time of read operation to read data. The bit line signal voltage difference is a difference between the bit line voltages at the times when the read data is “1” and “0”. Due to small differences of the bit line signal voltages, the small scale memory cell array is likely to have difficulty in reading data.

### SUMMARY OF THE INVENTION

An aspect of the present invention provides a ferroelectric memory device comprising a plate line, bit lines, first memory cells to store information, each of the first memory cells being connected between a corresponding one of the bit lines and the plate line, and each of the first memory cells including a first ferroelectric capacitor and of a first insulated gate type field effect transistor provided as a memory cell transistor, word lines, each of the word lines being connected to a gate of a corresponding one of the first insulated gate type field effect transistors, sense amplifiers to amplify information, each of the sense amplifiers being connected to a corresponding one of the bit lines, and a second ferroelectric capacitor having first and second terminals, the first terminals being electrically connected to a corresponding one of the bit lines, and the second terminals being electrically connected to a power supply.

Another aspect of the present invention provides a ferroelectric memory device comprising a plate line, bit lines, first memory cells to store information, each of the first memory cells being connected between a corresponding one of the bit lines and the plate line, and each of the first memory cells including a first ferroelectric capacitor and of a first insulated gate type field effect transistor as a memory cell transistor, word lines, each of the word lines being connected to a gate of a corresponding one of the first insulated gate type field effect transistors, sense amplifiers to amplify information, each of the sense amplifiers being connected to a corresponding one of the bit lines, a second ferroelectric capacitor having first and second terminals, the first terminals being electrically connected to a corresponding one of the bit lines, and the second terminal being electrically connected to a power supply, and a pre-charge circuit to pre-charge the second ferroelectric capacitor, the pre-charge circuit being connected to a corresponding one of the bit lines.

### BRIEF DESCRIPTION OF THE DRAWINGS

FIG. 1A is a block diagram showing a configuration of a ferroelectric memory device according to a first embodiment of the present invention.

FIG. 1B is a block diagram showing a structure of a memory cell block shown in FIG. 1.

FIG. 2 is a circuit diagram showing a memory cell array of FIG. 2.

FIG. 3 is a characteristic diagram showing a relationship between a bit line capacitance and a bit line signal voltage difference according to the first embodiment.

FIG. 4 is a block diagram showing a configuration of a ferroelectric memory device according to a second embodiment of the present invention.

FIG. 5 is a circuit diagram to show a main portion of a memory cell array according to the second embodiment.

FIGS. 6A and 6B are diagrams to explain a read operation according to the second embodiment.

FIG. 7 is a circuit diagram showing a main portion of a memory cell array according to a third embodiment.

FIG. 8 is a block diagram showing a configuration of a ferroelectric memory device according to a fourth embodiment.

### DETAILED DESCRIPTION OF THE INVENTION

Embodiments of the present invention will be described hereinafter with reference to the drawings.

A ferroelectric memory device according to a first embodiment of the present invention will be described with reference to drawings.

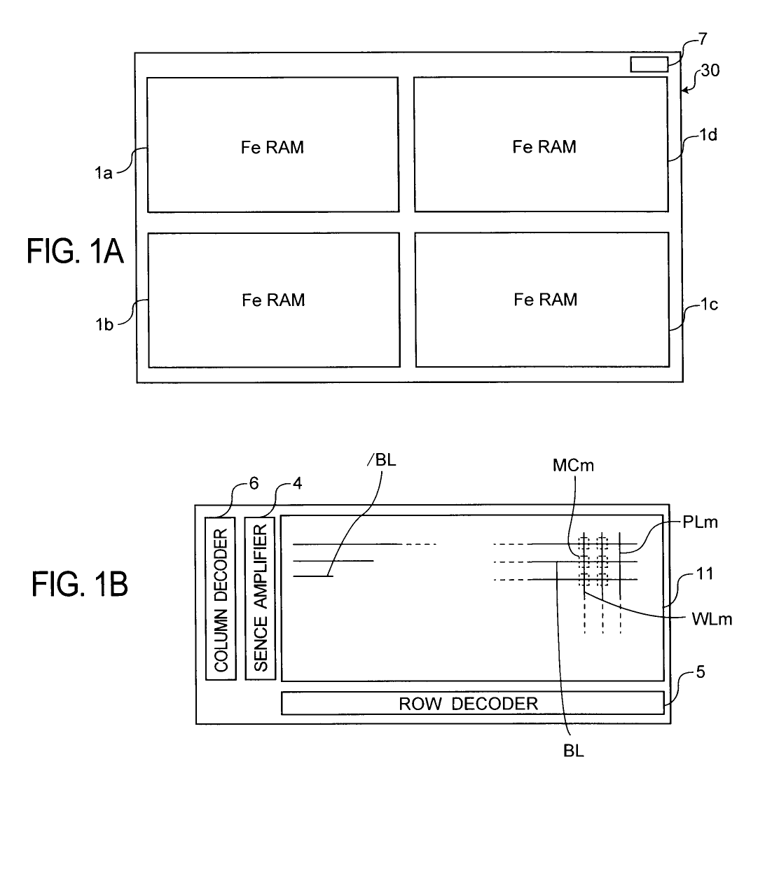

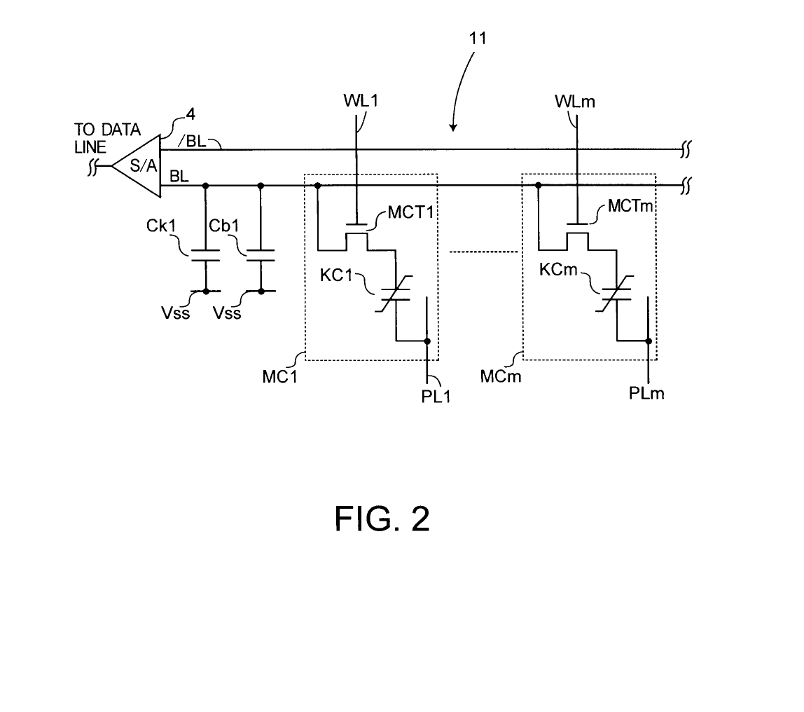

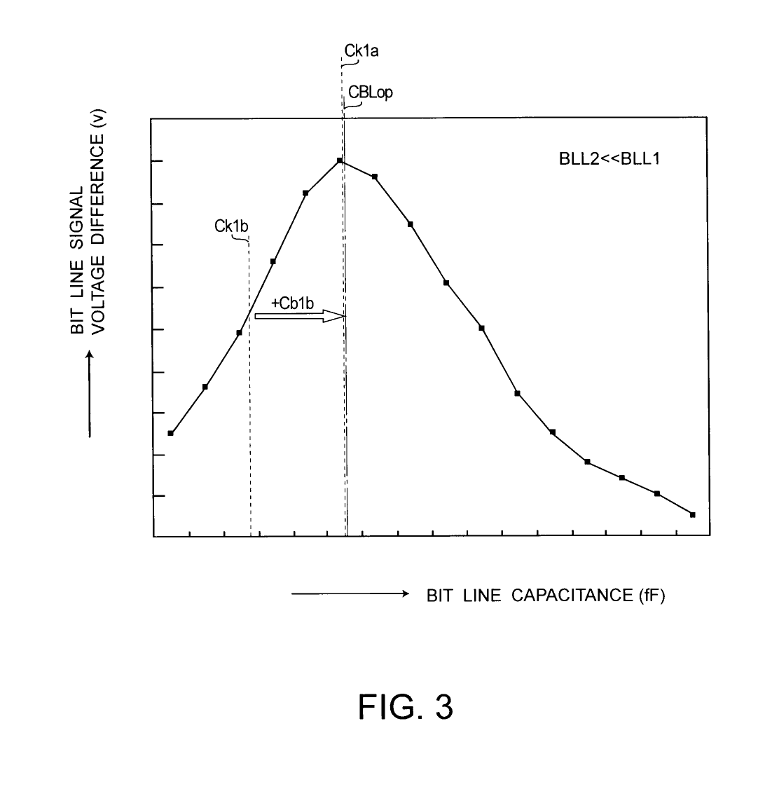

FIG. 1A is a block diagram showing a configuration of the ferroelectric memory device according to the first embodiment. FIG. 1B is a block diagram showing a structure of a memory cell block shown in FIG. 1A. FIG. 2 is a circuit diagram showing a main portion of a memory cell array of FIG. 1B. FIG. 3 is a characteristic diagram showing a relationship between a bit line capacitance and a bit line signal voltage difference.

As shown in FIG. 1A, a ferroelectric memory device 30 includes memory cell blocks 1a to 1d and a e-fuse 7. The memory cell blocks 1a to 1d are formed on the same semiconductor substrate. The memory cell blocks 1a to 1d constitute a main memory unit. The e-fuse 7 is arranged on an upper right edge portion of the ferroelectric memory device 30 in FIG. 1A. The memory cell blocks 1a to 1d have the same circuit configuration. The memory cell blocks 1a to 1d are arranged in upper left, lower left, lower right and upper right portions of the ferroelectric memory device 30, respectively.

The structure of each of the memory cell blocks 1a to 1d is shown in FIG. 1B. FIG. 1B shows a memory cell array 11 having a sense amplifier 4, a row decoder 5, a column decoder 6; and memory cells . . . , MCm. The memory cells . . . , MCm are arranged in a matrix. Each of the memory cells . . . , MCm is composed of a ferroelectric capacitor and a memory cell transistor (an insulated gate type field effect transistor).

The memory cells . . . , MCm constituting the memory cell array 11 are connected to bit lines BL and /BL, word lines . . . , WLm and plate lines . . . PLm.

The bit lines BL and /BL are arranged in a left and right direction in FIG. 1B. The word lines . . . , WLm and the plate line . . . , PLm are arranged in a upper and lower direction in FIG. 1B. The sense amplifier 4 is connected to the bit lines BL and /BL. The sense amplifier 4 amplifies information read from the memory cells . . . , MCm of the memory cell array 11 and then output the information to the outside. The sense amplifier 4 also amplifies data from the outside and writes the data to the memory cells . . . , MCm of the memory cell array 11.

The row decoder 5 is connected to the word lines . . . , WMm and the plate lines . . . , PLm. The column decoder 6 is connected to the gate of a column selection transistor (not shown) that is connected between a data line (not shown) and the bit lines BL and /BL.

The e-fuse 7 is a non-volatile memory. The e-fuse 7 is composed of a memory cell array of a smaller scale than each of the memory cell arrays of the memory cell blocks 1a to 1d. The memory cell array of the e-fuse 7 includes memory cells each being composed of a ferroelectric capacitor and a memory cell transistor. These memory cells are connected to bit lines, plate lines and word lines in the e-fuse 7, as in the case of the memory cells of the memory cell blocks 1a to 1d. The e-fuse 7 is provided with a sense amplifier and a row decoder, which are connected to bit lines and word lines, respectively, and a column decoder, in the same manner as the memory cell blocks 1a to 1d.

The e-fuse 7 is used to set such information as operation mode information for the memory cell blocks 1a to 1d. Such information is stored in the e-fuse 7. Application of a non-volatile memory such as a ferroelectric memory to an e-fuse is well-known. The e-fuse is generally used as the following. Information stored in an e-fuse is read out each time a relative device is started to be activated. The information read from the e-fuse is latched by a flip-flop or the like. The information latched is used as a fuse-information for the relative device.

The memory cell array 11 is configured as shown in FIG. 2. A memory cell MC1 is provided with a memory cell transistor MCT1 and a ferroelectric capacitor KC1, which are connected in series. A memory cell MCm is provided with a memory cell transistor MCTm and a ferroelectric capacitor KCm, which are connected in series. Each of the memory cells MC1, . . . MCTm is a 1T1C type memory cell. Each of the memory cell transistors MCT1, . . . MCTm is an insulated gate type field effect transistor.

In addition to the memory cells MC1, . . . , MCm, a bit-line insertion capacitor Cb1 and a bit-line parasitic capacitance Ck1 are connected to the bit line BL. Likewise, a bit-line insertion capacitor and a bit-line parasitic capacitance are connected to the bit line /BL in addition to memory cells (not shown).

The gate of the memory cell transistor MCT1 is connected to the word line WL1, and one of the source and drain of the memory cell transistor MCT1 is connected to the bit line BL. The other of the source and drain of the memory cell transistor MCT1 is connected to one end as (a first terminal) of the ferroelectric capacitor KC1. The other end (a second terminal) of the ferroelectric capacitor KC1 is connected to the plate line PL1.

The gate of the memory cell transistor MCTm is connected to the word line WLm. One of the source and drain of the memory cell transistor MCTm is connected to the bit line BL. The other of the source and drain of the memory cell transistor MCTm is connected to one end (a first terminal) of the ferroelectric capacitor KCm.

The other end (a second terminal) of the ferroelectric capacitor KCm is connected to the plate line PLm. A PZT (lead zirconium titanate: PbZrTiO₃) film, for example, is used for the ferroelectric film of each of the ferroelectric capacitors KC1, . . . , KCm. It should be noted that the number of memory cells MC1, . . . , MCm constituting the memory cell array 11 is greater than the number of memory cells constituting the memory cell array of the e-fuse 7.

One end of the bit-line insertion capacitor Cb1 is connected to the bit line BL, and the other end of the bit-line insertion capacitor Cb1 is connected to a low potential side power supply Vss, which supplies the ground potential.

As the materials of the bit-line insertion capacitors Cb1, a ferroelectric film such as a PZT film or a SBT film may be used. Other than the ferroelectric film such as a PZT film or a SBT film, a high dielectric film such as a niobium pentoxide (Nb₂O₅) film or a titanium oxide (TiO₂) film may be used as the material of the bit-line insertion capacitor Cb1. It should be noted that a niobium pentoxide (Nb₂O₅) film or a titanium oxide (TiO₂) film has a larger relative dielectric constant than the gate insulation film of each of the memory cell transistors MCT1, . . . , MCTm.

The bit-line parasitic capacitance Ck1 is a parasitic capacitance formed between the bit line BL and the low potential side power supply Vss. The bit-line parasitic capacitance Ck1 is composed of a capacitance between adjacent bit lines, the diffusion layer capacitance of the memory cell transistor or the like. For this reason, when the bit lines are long, and as the scale of the memory cell array becomes larger, the bit-line parasitic capacitance Ck1 becomes large.

FIG. 3 shows a relationship between a bit line capacitance and a difference of bit line signal voltages at the time of a read operation to read data. The difference of bit line signal voltages is a difference between the bit line voltages at the times when the data are “1” and “0”. In a case where the bit line capacitance is small, the value of the bit line signal voltage difference is small. As the bit line capacitance becomes larger, the value of the bit line signal voltage difference becomes large. When the bit line capacitance becomes further larger, the bit line signal voltage difference decreases.

The optimum bit line capacitance is a bit line capacitance which renders the value of the bit line signal quantity difference maximum. The optimum bit line capacitance is determined by the characteristics, the size or the like of the ferroelectric capacitor constituting the memory cell.

Here, the relationship between a bit line length BLL1 of each of the memory cell arrays of the memory blocks 1a to 1d and a bit line length BLL2 of the memory cell array of the e-fuse 7 is expressed by the following formula.

BLL2<<BLL1 (1)

Accordingly, the relationship between the bit line capacitance Ck1a of each of the memory cell arrays of the memory cell blocks 1a to 1d and the bit line capacitance Ck1b of the memory cell array of the e-fuse 7 is expressed by the following formula.

Ck1b<<Ck1a (2)

The configuration of the memory cells MC1, . . . , MCm of each of the memory cell arrays of the memory cell blocks 1a to 1d, and the configuration of the memory cells of the memory cell array of the e-fuse 7 are the same. Accordingly, the memory cell blocks 1a to 1d and the e-fuse 7 have an optimum bit line capacitance CBLop of the same value.

Normally, the bit line capacitance Ck1a of each of the memory cell blocks 1a to 1d is set to be a value close to the optimum bit line capacitance CBLop. The relationship between the bit line capacitance Ck1a of each of the memory cell blocks 1a to 1d and the optimum bit line capacitance Ck1b of the e-fuse 7 and the optimum bit line capacitance CBLop is expressed by the following formula.

Ck1b<<Ck1a≈CBLop (3)

Here, by inserting the bit-line insertion capacitor having a capacitance Cb1b to the bit lines of the memory cell array of the e-fuse 7, the bit line capacitance of the memory cell array of the e-fuse 7 can be set to the optimum bit line capacitance CBLop as shown in FIG. 3.

As described above, since the bit line capacitance of each of the memory cell arrays in the memory cell blocks 1a to 1d is set to a value close to the optimum bit line capacitance, it is normally not necessary to insert the bit-line insertion capacitor Cb1 to each of the memory cell arrays in the memory cell block 1a to 1d. In a case where the bit line capacitance Ck1a of each of the memory cell arrays in the memory cell blocks 1a to 1d is significantly smaller than the optimum bit line capacitance CBLop, it is preferable to insert the bit-line insertion capacitor Cb1 to the bit lines BL and /BL of each of the memory cell arrays in the memory cell blocks 1a to 1d, as in the case of the e-fuse 7.

As described above, the bit-line insertion capacitor can be connected to each of the bit lines of the memory cell blocks 1a to 1d and of the e-fuse 7. One end of the bit-line insertion capacitor is connected to the bit line, and the other end is connected to the low potential side power supply Vss, which is the ground potential. The bit-line insertion capacitor is composed of a ferroelectric film, and serves to set the bit line capacitance to be the optimum value.

Although the bit line lengths of the memory cell blocks 1a to 1d and the e-fuse 7 are different, by setting the capacitance value of the bit-line insertion capacitor to an appropriate value, each of the bit line capacitances can be set to be the optimum value. Thereby, the difference of the bit line signal voltage can be the maximum.

It should be noted that 1T1C type memory cells are used for the memory cells MC1, . . . , MCm in this embodiment. Instead of 1T1C type, 2T2C type memory cells each being composed of two memory cell transistors and two ferroelectric capacitors may be used for the memory cells MC1, . . . , MCm.

In this embodiment, the memory cell transistor MCTm of the memory cell array 11 and the ferroelectric capacitor MCm are connected in series. The present invention is also applied to so-called Chain FeRAM in which memory cells each being composed of a memory cell transistor and a ferroelectric capacitor connected in parallel to each other are connected in series.

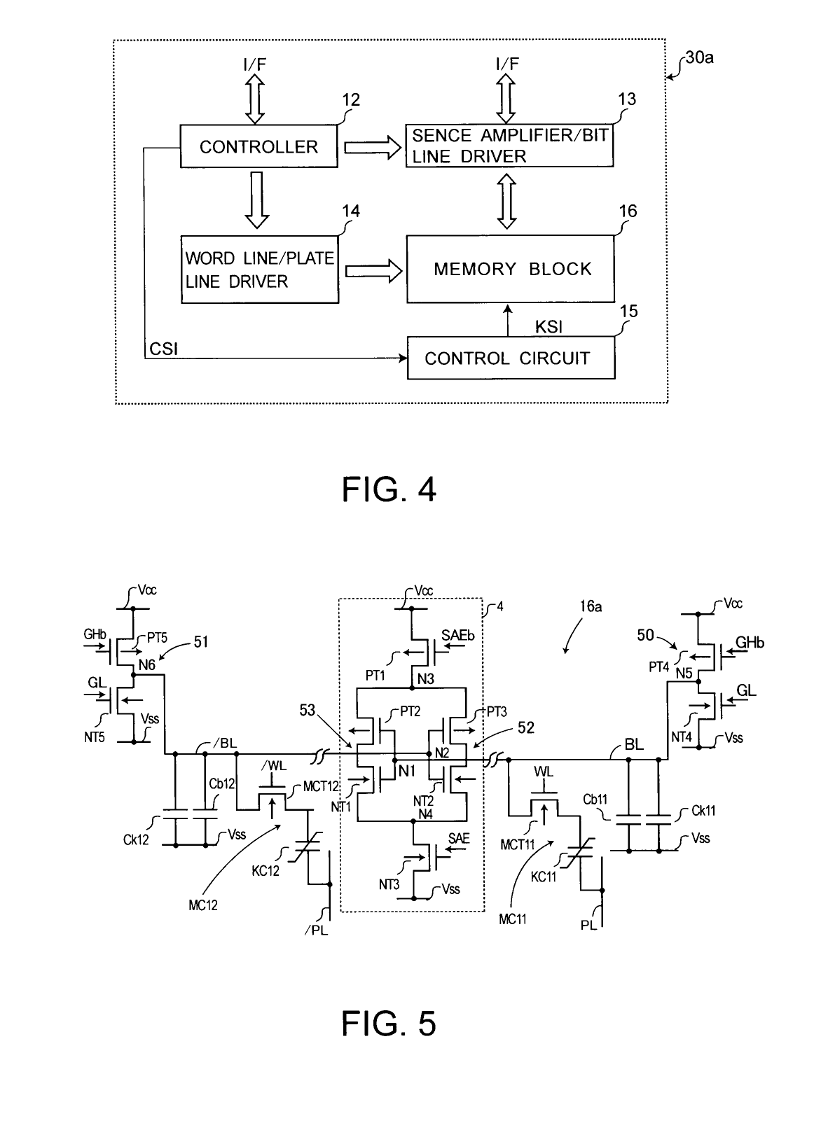

A ferroelectric memory device according to a second embodiment of the present invention will be described with reference to FIGS. 4 and 5. FIG. 4 is a block diagram showing a configuration of the ferroelectric memory device 30a according to the second embodiment. FIG. 5 is a circuit diagram showing a main portion of a memory cell array according to second embodiment.

As shown in FIG. 4, the ferroelectric memory device 30a is provided with a memory block 16, a controller 12, a sense amplifier/bit line driver 13, a word line/plate line driver 14, and a control circuit 15. The ferroelectric memory device 30a constitutes FeRAM.

The memory block 16 includes a memory cell array 16a composed of memory cells arranged and formed in a matrix as shown in FIG. 5. In FIG. 5, bit lines BL and /BL, word lines WL and /WL, and plate lines PL and /PL are arranged in the memory cell array 16a. Memory cells MC11, MC 12, . . . are respectively composed of ferroelectric capacitors KC11, KC12, . . . and N-channel memory cell transistors MCT11, MCT12, . . . each being as an insulated gate type field effect transistor. As shown in FIG. 4, the controller 12 exchanges information with an interface (I/F), and outputs various control signals to the sense amplifier/bit line driver 13 and the word line/plate line driver 14.

The sense amplifier/bit line driver 13 exchanges information with the interface (I/F), and drives the bit lines in accordance with a control signal outputted from the controller 12. The sense amplifier/bit line driver 13 also amplifies the potentials of the bit lines BL and /BL by an unillustrated sense amplifier 4, and then reads out the potentials to the outside. The word line/plate line driver 14 drives the word lines WL and /WL and the plate lines PL and /PL in accordance with a control signal outputted from the controller 12.

The controller 15 receives a control signal CS1 outputted from the controller 12. The controller 15 outputs in advance, to the memory cell array 16a, before reading information from the memory cell, a control signal KS1 for precharging (writing) bit-line insertion capacitors Cb11 and Cb12. Here, each of the bit-line insertion capacitors Cb11 and Cb12 is composed of a ferroelectric film that is inserted for setting the bit line capacitance of the memory cell array 16a of FIG. 5 to have the optimum value. The aforementioned control signal CS1 includes a control signal or a timing signal.

A structure of the memory cell array 16a will be further described in detail. In FIG. 5, the drains of the MOS transistors MCT11, MCT12, . . . are connected to the bit lines BL and /BL, respectively. One end of the bit-line insertion capacitor Cb11 and one end of the bit line parasitic capacitance Ck11 are connected to the bit line BL. One end of the bit-line insertion capacitor Cb12 and one end of the bit line parasitic capacitance Ck12 are connected to the bit line /BL. The other end of the bit line capacitances Cb11 and the other end of the bit line parasitic capacitances Ck11 are connected to a low potential side power supply Vss. The other end of the bit line capacitances Cb12 and the other end of the bit line parasitic capacitances Ck12 are connected to a low potential side power supply Vss. The sense amplifier 4 is connectable to the bit lines BL and /BL via an unillustrated bit line selection MOS transistor.

The gates of the N-channel MOS transistor MCT11 and MCT12 . . . are connected to the word lines WL and /WL, respectively. The sources of the N-channel MOS transistor MCT11 and MCT12 . . . , are connected to the plate lines PL and /PL, respectively. In FIG. 5, one ends of the bit lines BL and BL/ are connected to output terminals N5 and N6 of pre-charge circuits 50 and 51, respectively. The pre-charge circuits 50 and 51 are respectively composed of series circuits including P-channel MOS transistors PT4 and PT5 and N-channel MOS transistors NT4 and NT5, respectively. As will be described later, the pre-charge circuits 50 and 51 are circuits respectively for precharging the bit-line insertion capacitors Cb11 and Cb12.

The sense amplifier 4 is provided with P-channel MOS transistors PT1 to PT3 and N-channel MOS transistors NT1 to NT3. The P-channel MOS transistors PT2 and PT3, and N-channel MOS transistors NT2 and NT3 are respectively connected in series, and thus constitute CMOS inverter circuits 52 and 53, respectively.

The source of the P-channel MOS transistor PT1 is connected to a high potential side power supply Vcc. The drain of the P-channel MOS transistor PT1 is connected to a node N3. A control signal SAEb is inputted to the gate of the P-channel MOS transistor PT1.

The source of the P-channel MOS transistor PT2 is connected to the node N3. The drain of the P-channel MOS transistor PT2 is connected to the drain of the N-channel MOS transistor NT1. The gate of the P-channel MOS transistor PT2 is connected to a node N1. The gate of the N-channel MOS transistor NT1 is connected to the node N1.

The source of the N-channel MOS transistor NT1 is connected to a node N4. The gate of the N-channel MOS transistor NT1 is connected to the node N1. The node N1 is connected to the bit line BL.

The source of the P-channel MOS transistor PT3 is connected to the node N3. The drain of the P-channel MOS transistor PT3 is connected to the drain of the N-channel MOS transistor NT2. The gate of the P-channel MOS transistor PT3 is connected to the node N2. The gate of the N-channel MOS transistor NT2 is connected to the node N2.

The source of the N-channel MOS transistor NT2 is connected to the node N4. The node N2 is connected to the bit line /BL.

The drain of the N-channel MOS transistor NT3 is connected to the node N4. The source of the N-channel MOS transistor NT3 is connected to a low potential side power supply Vss, which supplies the ground potential. A control signal SAE, which is a signal having a phase opposite to the control signal SAEb, is inputted to the gate of the N-channel MOS transistor NT3.

The gate of the memory cell transistor MCT11 constituting the memory cell MC11 is connected to the word line WL.

The gate of the memory cell transistor MCT12 constituting the memory cell MC12 is connected to the word line /WL. A PZT (lead zirconium titanate: PbZrTiO₃) film, for example, can be used for the ferroelectric film of each of the ferroelectric capacitors KC11 and KC12.

As the materials of the bit-line insertion capacitors Cb11 and Cb12, a ferroelectric film such as a PZT film or an SBT film may be used.

The bit line parasitic capacitance Ck11 is a parasitic capacitance formed between the bit line BL and the low potential side power supply Vss, and is composed of a capacitance between adjacent bit lines, the diffusion layer capacitance of the memory cell transistor MCT11 . . . or the like. The bit line parasitic capacitance Ck12 is a parasitic capacitance formed between the bit line /BL and the low potential side power supply Vss, and is composed of a capacitance between adjacent bit lines, the diffusion layer capacitance of the memory cell transistor MCT12 . . . or the like.

The source (a first terminal) of the P-channel MOS transistor PT4 is connected to a high potential side power supply Vcc. The drain (a second terminal) of the P-channel MOS transistor PT4 is connected to the node N5. A control signal GHb is inputted to the gate (a control terminal) of the P-channel MOS transistor PT4. The drain (a second terminal) of the N-channel MOS transistor NT4 is connected to the node N5. The source (a first terminal) of the N-channel MOS transistor NT4 is connected to a low potential side power supply Vcc. A control signal GL is inputted to the gate (a control terminal) of the N-channel MOS transistor NT4. Here, by setting the control signals GHb and GL to be at a “Low” level, the voltage of the node N5 connected to the bit line BL can be at the Vcc level. Thereby, the bit-line insertion capacitor Cb11 connected to the bit line BL can be set to a write condition before the read operation.

The source (a first terminal) of the P-channel MOS transistor PT5 is connected to a high potential side power supply Vcc. The drain (a (second terminal) of the P-channel MOS transistor PT5 is connected to the node N6. A control signal GHb is inputted to the gate (a control terminal) of the P-channel MOS transistor PT5.

The drain (a second terminal) of the N-channel MOS transistor NT5 is connected to the node N6. The source (a first terminal) of the N-channel MOS transistor NT5 is connected to a low potential side power supply Vss. A control signal GL is inputted to the gate (a control terminal) of the N-channel MOS transistor NT5. Here, by setting the control signals GHb and GL to be at a “Low” level, the voltage of the node N6 connected to the bit line /BL can be at the Vcc level. Thereby, the bit-line insertion capacitor Cb12 connected to the bit line /BL can be pre-charged before the read operation. It should be noted that although the control signals GHb and GL are configured to be outputted from the control circuit 15, the signals can be outputted from the controller 12 instead of the control circuit 15.

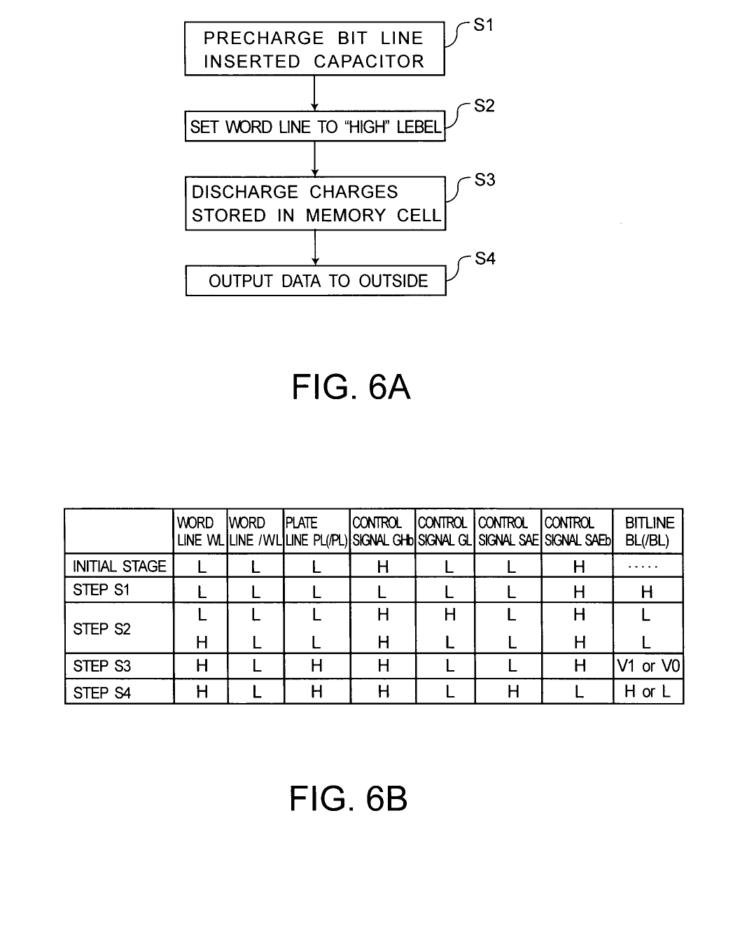

An operation of the ferroelectric memory device according to the second embodiment will be described with reference to FIGS. 6A and 6B. FIG. 6A is a flowchart showing a read operation of the ferroelectric memory device. FIG. 6B is a diagram for specifically explaining a read sequence of the ferroelectric memory device. In FIG. 6B, “H” and “L” indicate a “High” level and a “Low” level, respectively.

The read operation of the ferroelectric memory device 30 will be described. In the first stage, which is a stage before the beginning of the read operation, the control signals GHb and SAEb are set at the “Vcc” level, which is the “High” level. In addition, the word lines WL and /WL, the plate line PL and the control signals GL and SAE are set at the “Vss (0V)” level, which is the “Low” level.

As shown in FIG. 6A, in the read operation, the bit-line insertion capacitors Cb11 and Cb12 are first pre-charged by supplying electric charges to the bit-line insertion capacitors Cb11 and Cb12 (step S1).

In this state, the level of the control signal GHb is changed from the “Vcc” level, which is the “High” level, to a “0V” level, which is the “Low” level. Thereby, the voltages of the bit lines BL and /BL are increased from the “0V” level, which is the “Low” level, to the “Vcc” level, which is the “High” level. Thus, the bit-line insertion capacitors Cb11 and Cb12 become the pre-charged state in which the “Vcc” level is written in the bit-line insertion capacitors Cb11 and Cb12.

In a normal write operation of the ferroelectric memory device, by setting the word lines to be at the “High” level, and the memory cell transistors to be “ON,” data is written in the ferroelectric capacitor constituting the memory cell. In the read operation according to the second embodiment, however, the bit-line insertion capacitors Cb11 and Cb12 first become the written state.

By setting the bit-line insertion capacitors Cb11 and Cb12 to be in the state where the “Vcc” level is written, the polarization directions of the bit-line insertion capacitors Cb11 and Cb12 each composed of the ferroelectric capacitor are aligned. Accordingly, during the process of the read operation performed by the steps after step S1 in FIG. 6A, the inversion of the polarization of the bit-line insertion capacitors Cb11 and Cb12 can be prevented. An occurrence of a read error can be thus eliminated.

The word line WL is set at the “High” level (step S2) in FIG. 6A. Specifically, as shown in FIG. 6B, by changing the control signal GL from the “0V” level, which is the “Low” level, to the “Vcc” level, which is the “High” level, the bit lines BL and /BL are pre-charged from the “Vcc” level to the “0” level in advance. Then, the word line WL is set at the “High” level.

The plate line PL is changed from the “0v” level, which is the “Low” level, to the “Vcc” level, which is the “High” level. Thereby, the accumulated electric charges of the ferroelectric capacitors KC11 and KC12 of the memory cell are released to the bit line BL, and then inputted to the sense amplifier 4 (step S3). Furthermore, the information amplified by the sense amplifier 4 is outputted to the outside via a data line (step S4).

According to this embodiment, in addition to the same effects as those of the first embodiment, the bit-line insertion capacitors Cb11 and Cb12 can be pre-charged in advance before data is read from the memory cells MC11 and MC12.

Accordingly, in the process of reading data, the inversion of the polarization of the bit-line insertion capacitors Cb11 and Cb12 can be prevented. Thus, occurrence of reading error can be reduced.

Although the ferroelectric memory device 30a is composed of a MOS transistor in this embodiment, MISFET (Metal Insulator Semiconductor Field Effect Transistor) using a dielectric film (High-K gate insulation film) for the gate insulation film, for example, may be used.

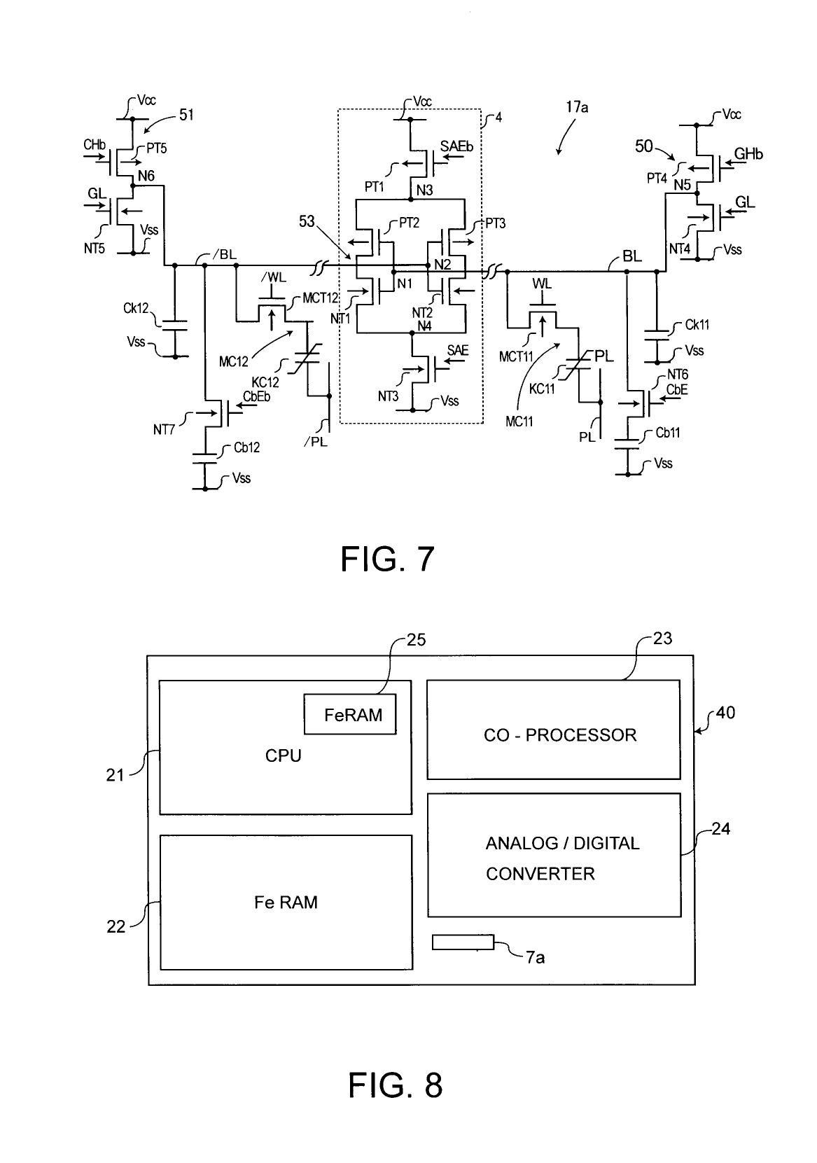

A ferroelectric memory device according to a third embodiment will be described with reference to FIG. 7. FIG. 7 is a circuit diagram showing a configuration of a main portion of a memory cell array according to the aforementioned third embodiment.

In FIG. 7, the same components as those of the second embodiment are denoted by the same reference numerals.

The third embodiment shown in FIG. 7 is different from the second embodiment of FIG. 5 in the following structure. In a memory cell array 17a, series circuits composed of N-channel MOS transistor NT6 and the bit-line insertion capacitor Cb11 as well as N-channel MOS transistor NT7 and the bit-line insertion capacitor Cb12 are respectively connected to the bit lines BL and /BL. The other portions are the same as those of the second embodiment.

The drain of the N-channel MOS transistor NT6 is connected to the bit line BL. The source of the N-channel MOS transistor NT6 is connected to one end of the bit-line insertion capacitor Cb11. The other end of the bit-line insertion capacitor Cb11 is connected to a low potential side power supply Vss, which is the ground voltage. A control signal CbE is inputted to the gate (a control terminal) of the N-channel MOS transistor NT6.

The drain of the N-channel MOS transistor NT7 is connected to the bit line /BL. The source of the N-channel MOS transistor NT7 is connected to one end of the bit-line insertion capacitor Cb12. The other end of the bit-line insertion capacitor Cb12 is connected to a low potential side power supply voltage Vss, which is the ground potential.

A control signal CbEb that is a signal having the same phase as that of the control signal CbE is inputted to the gate (control terminal) of the N-channel MOS transistor NT7.

The control signals CbE and CbEb are control signals for precharging (writing) the bit-line insertion capacitors Cb11 and Cb12, respectively.

When the control signals CbE and CbEb are at the “High” level, the N-channel MOS transistors NT6 and NT7 are turned “ON,” and thereby, the bit-line insertion capacitors Cb11 and Cb12 are electrically connected to the bit lines BL and /BL, respectively.

For this reason, the bit-line insertion capacitors Cb11 and Cb12 can be separated from the bit lines BL and /BL, respectively, by the corresponding control signal CbE and CbEb. The bit lines bit-line insertion capacitors Cb11 and Cb12 need to be respectively connected to the bit lines BL and /BL, at the time of the read operation, but do not need to be respectively connected to the bit lines BL and /BL at the time of the writing operation. Rather, when the bit lines insertion capacitors Cb11 and Cb12 are respectively connected to the bit lines BL and /BL, the bit line capacitances become larger, and it takes longer time to change the potential of the bit lines.

According to the present embodiment, the bit-line insertion capacitors can be separated from the bit lines BL and /BL when the bit-line insertion capacitors Cb11 and Cb12 are not necessary at the time of the writing operation. Thereby, the bit line capacitance can be reduced and the writing speed can be faster as well.

Although the controller circuit 15 generates the control signals CbE and CbEb in the third embodiment, the controller 12 may generate the control signal CbE and CbEb.

A ferroelectric memory device according to a fourth embodiment will be described with reference to FIG. 8. FIG. 8 is a block diagram showing a structure of a main portion of the memory cell array according to the fourth embodiment.

In FIG. 8, a ferroelectric memory device 40 is provided with an e-fuse 7a, a CPU (central processing unit) 21, a memory cell block 22, a co-processor 23 and an A/D (analog-to-digital) converter 24. These units are formed on the same semiconductor chip.

The memory cell block 22 has the same configuration as that of the ferroelectric memory device of FIG. 1B, and is used as a main memory.

The CPU 21 includes a ferroelectric memory device 25 having a memory cell array of a medium scale smaller than the memory cell array of the memory cell block 22. The ferroelectric memory device has the same configuration as that of the ferroelectric memory device of FIG. 1B except for the scale of the memory array. The CPU 21 manages and controls the entire ferroelectric memory device 40 of a combination type. The ferroelectric memory device 25 is configured to store a program or information therein.

The e-fuse 7a is provided with a ferroelectric memory device having a small scale of memory cell array that is smaller than that of the memory cell array of the memory cell block 22. The ferroelectric memory device has the same configuration as that of the ferroelectric memory device of FIG. 1B except for the scale of the memory array, and is configured to store redundancy information or operation mode information therein.

The coprocessor 23 aids the CPU 21, and is an auxiliary processor that performs arithmetic processing such as encoding processing, or I/O processing or image processing.

In a case where a need for embedding a memory in the coprocessor 23 arises as the scale of the coprocessor 23 increases, it is preferable that the coprocessor 23 should include a ferroelectric memory device similar to the one shown in FIG. 1B.

Upon receipt of an analog signal inputted to the A/D converter 24 via an unillustrated input/output interface, the A/D converter 24 supplies an analog-to-digital converted signal to the ferroelectric memory device 40 of a combination type.

The relationship of a bit line length BLLA of the memory cell array of the memory cell block 22, a bit line length BLLB of the memory cell array of the ferroelectric memory device 25 embedded in the CPU 21 and a bit line length BLLc of the memory cell array of the e-fuse 7 is expressed by the following formula.

BLLC<BLLB<BLLA (4)

The relationship of a bit line capacitance CBkA of the memory cell array of the memory cell block 22, a bit line capacitance CBkB of the memory cell array of the ferroelectric memory device 25, a bit line capacitance CBkC of the memory cell array of the e-fuse 7 and the optimum bit line capacitance CBLop is expressed by the following formula.

CBkC<CBkB<CBkA≈CBLop (5)

Here, bit-line insertion capacitors each being composed of a ferroelectric capacitor are respectively inserted to the bit lines of: the memory cell arrays of the ferroelectric memory device 25; and the memory cell arrays of the e-fuse 7.

Accordingly, the optimum value can be set to each of the bit line capacitances of: the memory cell arrays of the memory cell block 22; the memory cell arrays of the ferroelectric memory device 25; and the memory cell arrays of the e-fuse 7. Thus, each of the differences of the bit signal voltages can be the maximum.

For this reason, when memory cell arrays have a different bit line length from each other, bit-line insertion capacitors of ferroelectric films may have a different capacitance value from each other respectively. The bit-line insertion capacitors are connected between the bit lines and the power supply Vss of a lower potential (a ground potential).

Accordingly, an optimum value may be set to each of the bit line capacitances of the memory cell arrays, and each of the differences of the bit line signal voltages can be set to the maximum.

In the aforementioned first embodiment, the memory cells constituting the memory cell arrays of the memory cell blocks 1a to 1d for the main memory, and the memory cells constituting the memory cell array of the e-fuse 7 have the same circuit configuration. These memory cells, however, may have a different circuit configuration.

For example, the memory cell arrays of the memory cell blocks 1a to 1d may be composed of Chain FeRAM, and the memory cell array of the e-fuse 7 may be composed of 1T1C type. Although a plurality of plate lines are used in the aforementioned embodiments, the number of plate lines may be one. In addition, although the e-fuse 7 is provided in the first and the fourth embodiments, the e-fuse 7 may be provided in the second or the third embodiment as well.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A ferroelectric memory device comprising:
a plate line;
bit lines;
first memory cells to store information, each of the first memory cells being connected between a corresponding one of the bit lines and the plate line, and each of the first memory cells including a first ferroelectric capacitor and of a first insulated gate type field effect transistor provided as a memory cell transistor;
word lines, each of the word lines being connected to a gate of a corresponding one of the first insulated gate type field effect transistors;
sense amplifiers to amplify information, each of the sense amplifiers being connected to a corresponding one of the bit lines; and
a second ferroelectric capacitor having first and second terminals, the first terminals being electrically connected to a corresponding one of the bit lines, and the second terminals being electrically connected to a power supply.

2. The ferroelectric memory device as recited in claim 1, wherein the first terminal of the second ferroelectric capacitor is directly connected to the corresponding one of the bit lines, and the second terminal of the second ferroelectric capacitor is directly connected to the power supply.

3. The ferroelectric memory device as recited in claim 1, wherein in each of the first memory cells, the first ferroelectric capacitor and the first insulated gate type field effect transistor are connected to each other in parallel.

4. The ferroelectric memory device as recited in claim 1, wherein
in each of the first memory cells, the first ferroelectric capacitor and the first insulated gate type field effect transistor are connected to each other in series.

5. The ferroelectric memory device as recited in claim 1, further comprising an e-fuse, wherein the e-fuse includes:
a plate line;
bit lines;
second memory cells to store information, each of the second memory cells being connected between a corresponding one of the bit lines and the plate line, and each of the second memory cells having a third ferroelectric capacitor and a second insulated gate type field effect transistor as a memory cell transistor;
word lines, each of the word lines being connected to a gate of a corresponding one of the transistors; and
a fourth ferroelectric capacitor having first and second terminals, the first terminal being electrically connected to a corresponding one of the bit lines, and the second terminal being electrically connected to a power supply.

6. The ferroelectric memory device as recited in claim 5, wherein each of the bit lines connected to the second memory cells of the e-fuse is shorter than each of the bit lines connected to the first memory cells.

7. The ferroelectric memory device as recited in claim 1, wherein a relative dielectric ratio of the second ferroelectric capacitor is greater than a relative dielectric ratio of the first insulated gate type field effect transistor.

8. A ferroelectric memory device comprising:
a plate line;
bit lines;
first memory cells to store information, each of the first memory cells being connected between a corresponding one of the bit lines and the plate line, and each of the first memory cells including a first ferroelectric capacitor and of a first insulated gate type field effect transistor as a memory cell transistor;
word lines, each of the word lines being connected to a gate of a corresponding one of the first insulated gate type field effect transistors;
sense amplifiers to amplify information, each of the sense amplifiers being connected to a corresponding one of the bit lines;
a second ferroelectric capacitor having first and second terminals, the first terminals being electrically connected to a corresponding one of the bit lines, and the second terminal being electrically connected to a power supply; and
a pre-charge circuit to pre-charge the second ferroelectric capacitor, the pre-charge circuit being connected to a corresponding one of the bit lines.

9. The ferroelectric memory device as recited in claim 8, wherein the pre-charge circuit includes complementary insulated gate type field effect transistors.

10. The ferroelectric memory device as recited in claim 8, wherein the pre-charge circuit pre-charges the second ferroelectric capacitor when all of the first insulated gate type field effect transistors connected to one of the bit lines are in an OFF state.

11. The ferroelectric memory device as recited in claim 8, wherein the second ferroelectric capacitor is pre-charged prior to an operation to read information from each the first memory cells to provide the information to a corresponding one of the sense amplifiers.

12. The ferroelectric memory device as recited in claim 8, wherein a relative dielectric ratio of the second ferroelectric capacitor is greater than a relative dielectric ratio of the first insulated gate type field effect transistor.

13. The ferroelectric memory device as recited in claim 8, wherein a second insulated gate type field effect transistor is connected between the first terminal of the second ferroelectric capacitor and a corresponding one of the bit lines.

14. The ferroelectric memory device as recited in claim 13, wherein the pre-charge circuit includes complementary insulated gate type field effect transistors.

15. The ferroelectric memory device as recited in claim 13, wherein the pre-charge circuit pre-charges the second ferroelectric capacitor when all of the first insulated gate type field effect transistors connected to one of the bit lines are in an OFF state.

16. The ferroelectric memory device as recited in claim 13, wherein the second ferroelectric capacitor is pre-charged prior to an operation to read information from each of the first memory cells to provide the information to a corresponding one of the sense amplifiers.

17. The ferroelectric memory device as recited in claim 13, wherein each of the second insulated gate type field effect transistors connected to one of the bit lines is set in an OFF state, when a write operation is performed for one of the first memory cells connected to the bit line.

18. The ferroelectric memory device as recited in claim 8, wherein, in each of the first memory cells, the first ferroelectric capacitor and the first insulated gate type memory cell transistor are connected to each other in parallel.

19. The ferroelectric memory device as recited in claim 8, wherein in each of the first memory cells, the first ferroelectric capacitor and the first insulated gate type field effect transistor are connected to each other in series.

20. The ferroelectric memory device as recited in claim 8, further comprising an e-fuse, wherein the e-fuse includes:
a plate line;
bit lines;
second memory cells to store information, each of the second memory cells being connected to a corresponding one of the bit lines and the plate line, and each of the second memory cells having a third ferroelectric capacitor and of a third insulated gate type field effect transistor as a memory cell transistor;
word lines, each of the word lines being connected to a gate of a corresponding one of the third insulated gate type field effect transistors; and
a fourth ferroelectric capacitor having first and second terminals, the first terminal of the fourth ferroelectric capacitor being electrically connected to a corresponding one of the bit lines, and the second terminal of the fourth ferroelectric capacitor being electrically connected to a power supply.
